(19) United States
(12) Patent Application Publication
(10) Pub. No.: US 2026/0123195 A1
(43) Pub. Date: Apr. 30, 2026

(54) DISPLAY DEVICE, ELECTRONIC DEVICE, AND METHOD FOR MANUFACTURING THE SAME

(71) Applicant: Samsung Display Co., Ltd., Yongin-si (KR)

(72) Inventors: Sung Hoon YANG, Yongin-si (KR); Hyun Eok SHIN, Yongin-si (KR); In Young JUNG, Yongin-si (KR)

(21) Appl. No.: 19/292,772

(22) Filed: Aug. 6, 2025

(30) Foreign Application Priority Data
Oct. 29, 2024 (KR) 10-2024-0149478

(51) Int. Cl. H10K 59/123; H10K 59/12; H10K 59/121

(52) U.S. Cl. CPC H10K 59/123; H10K 59/1201; H10K 59/1213

(57) ABSTRACT

A display device, a method for manufacturing the same and an electronic device are provided. The display device includes a substrate including a light emitting area and a non-light-emitting area, a light emitting element including a first semiconductor layer, a light emitting layer, and a second semiconductor layer, wherein the first semiconductor layer includes a first portion provided in the light emitting area and a second portion provided in the non-light-emitting area, a pad electrode on the second portion of the first semiconductor layer, a thin film transistor on the pad electrode, a pad insulating layer between the pad electrode and the thin film transistor, a pad connection electrode that connects the thin film transistor and the pad electrode and a common electrode on the light emitting element.

### CROSS-REFERENCE TO RELATED APPLICATION

The present application claims priority to and the benefit of Korean Patent Application No. 10-2024-0149478, filed on October 29, 2024, in the Korean Intellectual Property Office, the entire content of which is hereby incorporated by reference.

### BACKGROUND

### 1. Field

Embodiments of the present disclosure relate to a display device, an electronic device, and a method for manufacturing the same.

### 2. Description of the Related Art

The importance of display devices is increasing along with the development of multimedia. In response to this, various suitable types or kinds of display devices such as organic light emitting display (OLED) and liquid crystal display (LCD) are being used.

A display panel such as an organic light emitting display panel or a liquid crystal display panel is included as a device that displays an image of a display device. Among them, a light emitting display panel may include a light emitting element, for example, an inorganic light emitting element that uses an inorganic substance as a light emitting material.

Representative technologies that form semiconductor thin films of inorganic light emitting elements include MOCVD (Metal Organic CVD) and MBE (Molecular Beam Epitaxy). The substrate temperature should be maintained at about 1,000 to 1,100 °C to obtain a semiconductor thin film by these methods,

Accordingly, the substrate on which the semiconductor thin film of the inorganic light emitting element is formed is limited to single crystal sapphire (Al₂O₃), silicon (Si), silicon carbide (SiC), and/or the like, which have relatively high transformation temperatures.

However, in the case of sapphire substrates, it is difficult to produce large-area wafers of 6 inches or more, and the production cost is high, making it difficult to implement large-area displays such as large TV.

In sapphire substrates, deterioration problems such as distortion of the substrate itself due to thermal expansion of the substrate may occur, and damage to the thin film may be a problem due to differences in the lattice constant and thermal expansion coefficient of the semiconductor thin film formed on the substrate and the substrate.

When growing a semiconductor thin film on a single-crystal sapphire substrate using the MOCVD method, a process of transferring the light emitting element to a second substrate such as a glass substrate is utilized, for example, in the process of manufacturing a micro LED display.

When light emitting element transfer is utilized or required, the cost of manufacturing the light emitting element and the transfer process is high, so the production cost of the display increases significantly, and as a result, the production cost of large TV using light emitting elements such as micro LED increases.

Therefore, a technology to directly grow a semiconductor thin film on a substrate without a transfer process has become desirable.

### SUMMARY

Aspects and features of embodiments of the present disclosure provide a display device, an electronic device, and a manufacturing method including a parallel structure light emitting element and a thin film transistor by directly growing a semiconductor thin film on a substrate.

However, aspects of embodiments of the present disclosure are not restricted to the ones set forth herein. The above and other aspects of embodiments of the present disclosure will become more apparent to one of ordinary skill in the art to which the disclosure pertains by referencing the detailed description of the disclosure given below.

According to one or more embodiments of the present disclosure, a display device includes a substrate including a light emitting area and a non-light-emitting area, a light emitting element including a first semiconductor layer, a light emitting layer, and a second semiconductor layer, wherein the first semiconductor layer includes a first portion provided in the light emitting area and a second portion provided in the non-light-emitting area, a pad electrode on the second portion of the first semiconductor layer, a thin film transistor on the pad electrode, a pad insulating layer (e.g., a pad electrically insulating layer) between the pad electrode and the thin film transistor, a pad connection electrode that connects the thin film transistor and the pad electrode and a common electrode on the light emitting element. According to one or more embodiments, the display device includes a first organic layer that covers a side surface of the transistor, a source electrode and a drain electrode that penetrates the organic layer and respectively connected to a source and a drain of the transistor and a transistor insulating layer (e.g., transistor electrically insulating layer) that covers the source electrode and the drain electrode, but including an opening that exposes at least a portion of the drain electrode, and wherein the pad connection electrode is on the drain electrode exposed by the transistor insulating layer and contacts the pad electrode that penetrates the transistor insulating layer, the organic layer, and the pad insulating layer.

According to one or more embodiments, the pad connection electrode is between the light emitting element and the transistor.

According to one or more embodiments, the light emitting layer is on the first portion, and the second semiconductor layer is on the light emitting layer.

According to one or more embodiments, the first semiconductor layer is a semiconductor layer doped with an n-type dopant, and the second semiconductor layer is a semiconductor layer doped with a p-type dopant.

According to one or more embodiments, the light emitting element further includes a protective layer around (e.g., surrounding) a portion of a side surface and a top surface of a semiconductor layer provided in the light emitting area.

According to one or more embodiments, the light emitting element further includes a conductive layer (e.g., an electrically conductive layer) on the second semiconductor layer.

According to one or more embodiments, the light emitting element further includes an undoped semiconductor layer under the first semiconductor layer.

According to one or more embodiments, the display device further includes a reflective layer on the substrate and a buffer layer under the light emitting element above the reflective layer.

According to one or more embodiments, the display device further includes a second organic layer above the thin film transistor in the non-emission area and below the common electrode.

According to one or more embodiments of the present disclosure, a method for manufacturing a display device includes forming a first semiconductor layer, a light emitting layer, and a second semiconductor layer on a substrate, the etching the second semiconductor layer, the light emitting layer, and the first semiconductor layer, wherein the first semiconductor layer is formed with different thicknesses in a first portion and a second portion, thereby forming a light emitting element, forming a pad electrode on a second portion of the first semiconductor layer, forming a thin film transistor on the pad electrode and forming a pad connection electrode connecting the thin film transistor and the pad electrode.

According to one or more embodiments, the forming a thin film transistor on the pad electrode comprises, forming a pad insulating layer (e.g., a pad electrically insulating layer) covering the pad electrode, forming an active layer including a source area, a channel area, and a drain area on the pad insulating layer, the forming a gate insulating layer (e.g., a gate electrically insulating layer) on the active layer, and a gate electrode on the gate insulating layer, and then forming a first organic layer covering both the gate electrode and the active layer, the forming a source electrode connected to the source area and a drain electrode connected to the drain area by penetrating the first organic layer.

According to one or more embodiments, the forming a pad connection electrode connecting the thin film transistor and the pad electrode comprises, forming a transistor insulating layer (e.g., a transistor electrically insulating layer) covering the source electrode and the drain electrode, forming a connection hole penetrating the transistor insulating layer, the first organic layer, and the pad insulating layer to expose the pad electrode and forming a pad connection electrode connecting the drain electrode and the pad electrode through the connection hole.

According to one or more embodiments, the method further includes, prior to forming a first semiconductor layer, a light emitting layer, and a second semiconductor layer on the substrate, depositing a reflective layer on the substrate and forming a buffer layer on the reflective layer.

According to one or more embodiments, a second organic layer covering the pad connection electrode and the transistor is formed, and wherein a common electrode covering the second organic layer and the light emitting element is formed.

According to one or more embodiments, the substrate is at least one selected from a glass substrate, a stainless-steel substrate, and a polymer substrate.

According to one or more embodiments, the forming the light emitting element includes forming a protective layer around (e.g., surrounding) a side surface and one surface of the first semiconductor layer, the light emitting layer, and the second semiconductor layer of the first portion.

According to one or more embodiments, the pad connection electrode is formed between the light emitting element and the transistor.

According to one or more embodiments, in the forming the first semiconductor layer, the light emitting layer, and the second semiconductor layer on the substrate, an undoped semiconductor layer is formed between the substrate and the first semiconductor layer, and at least one of a conductive layer is formed on the second semiconductor layer.

According to one or more embodiments, the first semiconductor layer is a semiconductor layer doped with an n-type dopant, and the second semiconductor layer is a semiconductor layer doped with a p-type dopant.

According to the display device according to the embodiments, the display device according to one embodiment may provide a parallel structure light emitting element and a thin film transistor by directly growing a semiconductor thin film on a substrate.

However, the effects of embodiments of the present disclosure are not limited to the aforementioned effects, and various suitable other effects are included in the specification.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a plan view of a display device according to one embodiment.

FIG. 2 is a schematic layout diagram of a circuit of a display substrate of a display device according to one embodiment.

FIG. 3 is an equivalent circuit diagram of one pixel of a display device according to one embodiment.

FIG. 4 is a cross-sectional view illustrating an example of one pixel of a display substrate according to one embodiment.

FIG. 5 is an enlarged view of area A of FIG. 4 according to one embodiment.

FIG. 6 is a cross-sectional view illustrating an example of one pixel of a display substrate according to another embodiment.

FIG. 7 is a flowchart illustrating a method of manufacturing a display device according to one embodiment.

FIGS. 8 to 17 are example drawings to illustrate a method of manufacturing a display device according to one embodiment.

FIG. 18 illustrates a smart device including a display device according to one or more embodiments.

FIG. 19 illustrates a vehicle in which display devices according to one or more embodiments are used.

FIG. 20 is an example diagram illustrating a transparent display device including a display device according to one or more embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being "on" another layer or substrate, it can be directly on the other layer or substrate, or intervening layers may also be present. In contrast, when an element is referred to as being "directly on" another element, there may be no intervening elements present.

Further, the phrase "in a plan view" means when an object portion is viewed from above, and the phrase "in a schematic cross-sectional view" means when a schematic cross-section taken by vertically cutting an object portion is viewed from the side.

The terms "overlap" or "overlapped" mean that a first object may be above or below or to a side of a second object, and vice versa. In embodiments, the term "overlap" may include layer, stack, face or facing, extending over, covering, or partly covering or any other suitable term as would be appreciated and understood by those of ordinary skill in the art. The expression "not overlap" may include meaning such as "apart from" or "set aside from" or "offset from" and any other suitable equivalents as would be appreciated and understood by those of ordinary skill in the art. The terms "face" and "facing" may mean that a first object may directly or indirectly oppose a second object. In embodiments in which a third object intervenes between a first and second object, the first and second objects may be understood as being indirectly opposed to one another, although still facing each other.

The spatially relative terms "below," "beneath," "lower," "above," "upper," or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in embodiments where a device illustrated in the drawing is turned over, the device "below" or "beneath" another device may be placed "above" another device. Accordingly, the illustrative term "below" may include both the lower and upper positions. The device may also be oriented in other directions and thus the spatially relative terms may be interpreted differently depending on the orientations.

When an element is referred to as being "connected" or "coupled" to another element, the element may be "directly connected" or "directly coupled" to another element, or "electrically connected" or "electrically coupled" to another element with one or more intervening elements disposed therebetween.

It will be further understood that when the terms "comprises," "comprising," "has," "have," "having," "includes" and/or "including" are used, they may specify the presence of stated features, integers, steps, operations, elements and/or components, but do not preclude the presence or addition of other features, integers, steps, operations, elements, components, and/or any combination thereof.

It will be understood that, although the terms "first," "second," "third," or the like may be used herein to describe various elements, these elements should not be limited by these terms. These terms are used to distinguish one element from another element or for the convenience of description and explanation thereof. For example, when "a first element" is discussed in the description, it may be termed "a second element" or "a third element," and "a second element" and "a third element" may be termed in a similar manner without departing from the spirit or scope of the present disclosure.

The terms "about" or "approximately" as used herein are inclusive of the stated value and means within an acceptable range of deviation for the particular value as determined by one of ordinary skill in the art, considering the measurement in question and the error associated with measurement of the particular quantity (for example, the limitations of the measurement system). For example, "about" may mean within one or more standard deviations, or within ± 30%, 20%, 10%, 5% of the stated value.

In the specification and the claims, the term "and/or" is intended to include any combination of the terms "and" and "or" for the purpose of its meaning and interpretation. For example, "A and/or B" may be understood to mean "A, B, or A and B." The terms "and" and "or" may be used in the conjunctive or disjunctive sense and may be understood to be equivalent to "and/or."

In the specification and the claims, the phrase "at least one of" is intended to include the meaning of "at least one selected from the group of" for the purpose of its meaning and interpretation. For example, "at least one of A and B" may be understood to mean "A, B, or A and B."

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described in more detail with reference to the accompanying drawings.

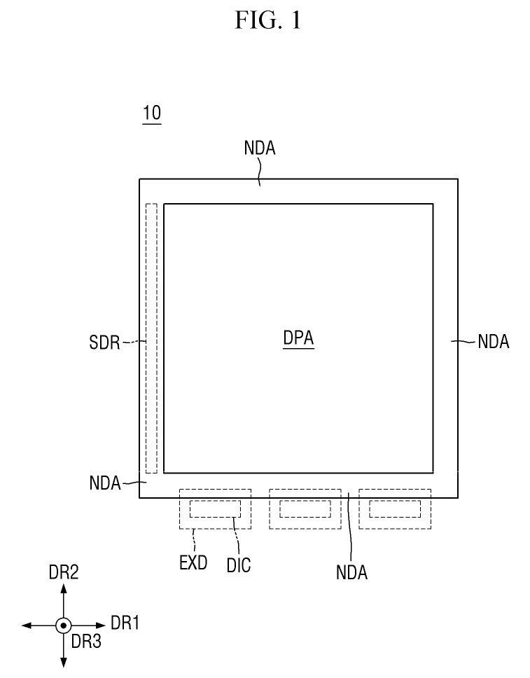

FIG. 1 is a plan view of a display device according to one embodiment.

Referring to FIG. 1, a display device 10 according to one embodiment may be applied to an electronic device such as, for example, a smartphone, cell phone, tablet PC, personal digital assistant (PDA), portable multimedia player (PMP), television, gaming device, wristwatch-type electronic device, head-mounted display, monitor of a personal computer, laptop computer, car navigation, car instrument panel, digital camera, camcorder, exterior billboard, billboard, medical device, testing device, various consumer electronics such as refrigerators and washing machines, or Internet of Things devices. In this specification, a television is described as an example of a display device, and the TV may have high or ultra-high resolution such as HD, UHD, 4K, 8K, and/or the like.

In embodiments, the display device 10 according to one embodiment may be classified in various suitable ways depending on the display method. For example, the classification of display device may include an organic light-emitting display device (OLED), an inorganic light-emitting display device (inorganic EL), a quantum dot light-emitting display device (QED), a micro-LED display device (micro-LED), a nano-LED display device (nano-LED), a plasma display device (PDP), a field emission display device (FED), a cathode ray display device (CRT), a liquid crystal display device (LCD), an electrophoretic display device (EPD), and/or the like. In the following, an organic light-emitting display device is used as an example to illustrate as a display device, and unless a special distinction is utilized or required, the organic light-emitting display device applied to the embodiment will be simply referred to as a display device. However, the embodiment is not limited to the organic light-emitting display device, and other display devices listed above or generally used in the art may be applied within the spirit and scope of the present disclosure.

Furthermore, in the following drawings, the first direction DR1 refers to the horizontal direction of the display device 10, the second direction DR2 refers to the vertical direction of the display device 10, and the third direction DR3 refers to the thickness direction of the display device 10. In embodiments, “left”, “right”, “up”, and “down” refer to directions when the display device 10 is viewed from a plane. For example, "right" refers to one side of the first direction DR1, "left" refers to the other side of the first direction DR1, "top" refers to one side of the second direction DR2, and "bottom" refers to the other side of the second direction DR2. Also, “top” refers to one side of the third direction DR3, and “bottom” refers to the other side of the third direction DR3.

The display device 10 according to one embodiment may have a square shape in a plan view, for example, a square shape. Also, if the display device 10 is a television, it may have a rectangular shape having a long side positioned in a horizontal direction. However, it is not limited thereto, and the long side may be positioned in a vertical direction and may be installed to be rotatable so that the long side may be variably positioned in the horizontal or vertical direction. Furthermore, the display device 10 may have a circular or oval shape (e.g., a generally circular or oval shape).

The display device 10 may include a display area DPA and a non-display area NDA. The display area DPA may be an active area where an image is displayed. The display area DPA may have a square shape in a plan view similar to the overall shape of the display device 10 but is not limited thereto.

A non-display area NDA may be around the display area DPA. The non-display area NDA may completely or partially surround the display area DPA. The display area DPA may have a square shape, and the non-display area NDA may be adjacent to four sides of the display area DPA. The non-display area NDA may form a bezel of the display device 10.

A driving circuit or driving element that drives the display area DPA may be provided in the non-display area NDA. In one embodiment, a pad portion is provided on the display substrate of the display device 10 in the non-display area NDA adjacent to the first side (lower side in FIG. 1) of the display device 10, and an external device EXD may be mounted on the electrode of the pad portion. Examples of the external device EXD include a connection film, a printed circuit board, a driving chip DIC, a connector, a wiring connection film, and/or the like. A scan driving portion SDR, and/or the like, directly on the display substrate of the display device 10 may be provided in the non-display area NDA adjacent to the second side (the left side in FIG. 1) of the display device 10.

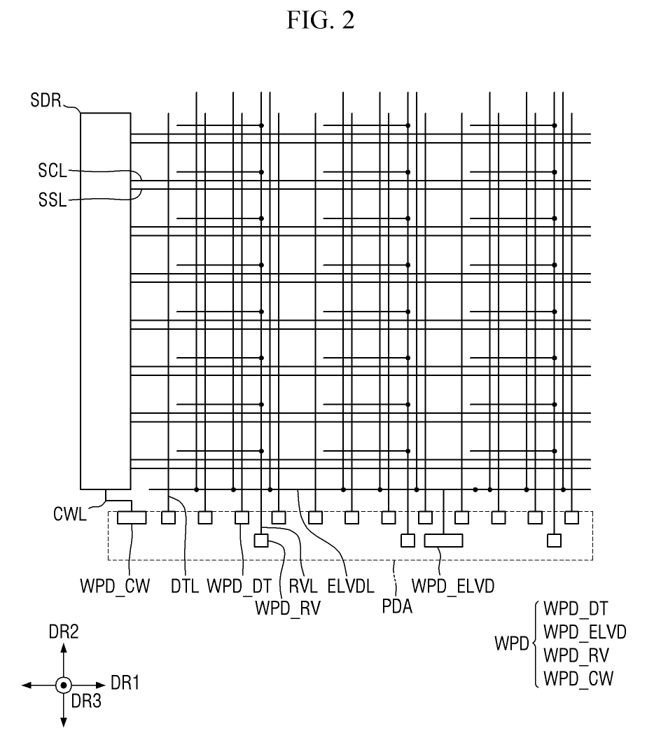

FIG. 2 is a schematic layout diagram of a circuit of a display substrate of a display device according to one embodiment.

Referring to FIG. 2, a plurality of wires are on a first substrate. The plurality of wires may include a scan line SCL, a sensing signal line SSL, a data line DTL, a reference voltage line RVL, a first power supply line ELVDL, and/or the like.

The scan line SCL and the sensing signal line SSL may extend in a first direction DR1. The scan line SCL and the sensing signal line SSL may be connected to a scan driving portion SDR. The scan driving portion SDR may include a driving circuit. The scan driving portion SDR may be on one side of a non-display area NDA on the display substrate, but is not limited thereto, and may be on both sides (e.g., two opposing sides) of the non-display area NDA. The scan driving portion SDR is connected to the signal connection line CWL, and at least one end of the signal connection line CWL may form a pad WPD_CW on the first non-display area NDA and/or the second non-display area NDA to be connected to an external device ('EXD' in FIG. 1).

The data line DTL and the reference voltage line RVL may extend in a second direction DR2 intersecting the first direction DR1. The first power supply line ELVDL may include a portion extending in the second direction DR2. The first power supply line ELVDL may further include a portion extending in the first direction DR1. The first power supply line ELVDL may have a mesh structure but is not limited thereto.

A wiring pad WPD may be on at least one end of the data line DTL, the reference voltage line RVL, and the first power supply line ELVDL. Each wiring pad WPD may be provided in a pad portion PDA of a non-display area NDA. In one embodiment, a wiring pad (WPD_DT, hereinafter referred to as a 'data pad') of a data line DTL, a wiring pad (WPD_RV, hereinafter referred to as a 'reference voltage pad') of a reference voltage line RVL, and a wiring pad (WPD_ELVD, hereinafter referred to as a 'first power pad') of a first power supply line ELVDL may be provided in the pad portion PDA of the non-display area NDA. In another example, the data pad WPD_DT, the reference voltage pad WPD_RV, and the first power supply pad WPD_ELVD may be provided in another non-display area NDA. An external device ('EXD' in FIG. 1) may be mounted on the wiring pad WPD as described above. The external device EXD may be mounted on the wiring pad WPD through an anisotropic conductive film (e.g., an anisotropic electrically conductive film), ultrasonic bonding, and/or the like.

Each pixel on the display substrate includes a pixel driving circuit. The above-described wirings may pass through each pixel or its surroundings and apply a driving signal to each pixel driving circuit. The pixel driving circuit may include a transistor and a capacitor. The number of transistors and capacitors of each pixel driving circuit may be modified in various suitable ways. In the following, the pixel driving circuit is described by taking a 3T1C structure including three transistors and one capacitor as an example but is not limited thereto and other various suitable modified pixel structures such as a 2T1C structure, a 7T1C structure, and a 6T1C structure may be applied.

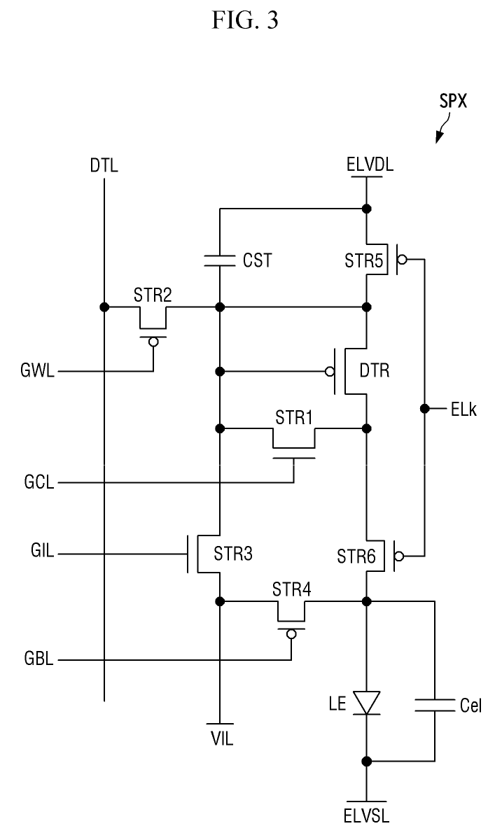

FIG. 3 is an equivalent circuit diagram of one pixel of a display device according to one embodiment.

Referring to FIG. 3, a plurality of pixel circuits PXC according to one embodiment may be connected to scan lines GWL, GIL, GCL, and GBL, light emitting lines ELk, and data lines DTL. For example, a sub-pixel SPX may be connected to a write scan line GWL, an initialization scan line GIL, a control scan line GCL, a bias scan line GBL, a light emitting line ELk, and a data line DTL.

The sub-pixel SPX according to one embodiment includes a driving transistor DTR, switching elements, a capacitor CST, and a light emitting element LE. The switching elements include first to sixth transistors ST1, ST2, ST3, ST4, ST5, and ST6.

The driving transistor DTR adjusts a current flowing from a first power supply line ELVDL to which a first power supply voltage is supplied to the light emitting element LE according to a voltage difference between a gate electrode and a source electrode. The gate electrode of the driving transistor DTR is connected to the first electrode of the first transistor STR1, the source electrode is connected to the first electrode of the light emitting element LE, and the drain electrode may be connected to the first power supply line ELVDL to which the first power supply voltage is applied.

The light emitting element LE may be a micro light emitting diode.

The light emitting element LE emits light according to the driving current Ids. The amount of light emitted by the light emitting element LE may be proportional to the driving current. The first electrode (e.g., the anode electrode) of the light emitting element LE is connected to a conductive layer (e.g., an electrically conductive layer) of the fourth transistor STR4 and the second electrode of the sixth transistor STR6, and the second electrode (e.g., the cathode electrode) may be connected to the second power supply line ELVSL to which the second power supply voltage is applied.

The capacitor C1 is formed between the second electrode of the driving transistor DTR and the first power supply line ELVDL to which the first power supply voltage is applied. The first power supply voltage may be a voltage of a higher level than the second power supply voltage. One electrode of the capacitor C1 may be connected to the second electrode of the driving transistor DTR, and the other electrode may be connected to the first power supply line ELVDL.

Some of the transistors STR2, STR4, STR5, and STR6 and the driving transistor DTR may all be formed of p-type MOSFET. In embodiments, the active layer of each of the p-type MOSFET transistors STR2, STR4, STR5, STR6, and DTR may be formed of polysilicon.

The gate electrode of the first transistor STR1 may be connected to the control scan line GCL, the gate electrode of the second transistor STR2 may be connected to the write scan line GWL, the gate electrode of the third transistor STR3 may be connected to the initialization scan line GIL, and the gate electrode of the fourth transistor STR4 may be connected to the bias scan line GBL.

The driving transistor DTR, the second transistor STR2, the fourth transistor STR4, the fifth transistor STR5, and the sixth transistor STR6 may be formed as p-type MOSFET, and the first transistor STR1 and the third transistor STR3 may be formed as n-type MOSFET. The active layers of each of the driving transistor DTR, the second transistor STR2, the fourth transistor STR4, the fifth transistor STR5, and the sixth transistor STR6 formed as p-type MOSFET may be formed of polysilicon, and the active layers of each of the first transistor STR1 and the third transistor STR3 formed as n-type MOSFET may be formed of oxide semiconductors.

Because the first transistor STR1 and the third transistor STR3 are formed as n-type MOSFET, the first transistor STR1 may be turned on when a scan signal of a gate high voltage is applied, and the third transistor STR3 may be turned on when an initialization scan signal of a gate high voltage is applied. In comparison, the driving transistor DTR, the second transistor STR2, the fourth transistor STR4, the fifth transistor STR5, and the sixth transistor STR6 are formed as p-type MOSFET, and thus may be turned on when a scan signal of a gate low voltage and a light emission signal are applied.

In embodiments, the first to sixth transistors ST1, ST2, ST3, ST4, ST5, and ST6 and the driving transistor DT may all be formed as n-type MOSFET. In embodiments, the active layers of each of the first to sixth transistors ST1, ST2, ST3, ST4, ST5, and ST6 and the driving transistor DT may be formed as oxide semiconductors.

In embodiments, the first to sixth transistors ST1, ST2, ST3, ST4, ST5, and ST6 and the driving transistor DT may all be formed as p-type MOSFET. In embodiments, the active layers of each of the first to sixth transistors ST1, ST2, ST3, ST4, ST5, and ST6 and the driving transistor DT may be formed of polysilicon.

Furthermore, the first power supply voltage of the first power supply line ELVDL, the second power supply voltage of the second power supply line ELVSL, and the third power supply voltage of the third power supply line VIL may be set in consideration of the characteristics of the driving transistor DTR, the characteristics of the light emitting element LE, and/or the like.

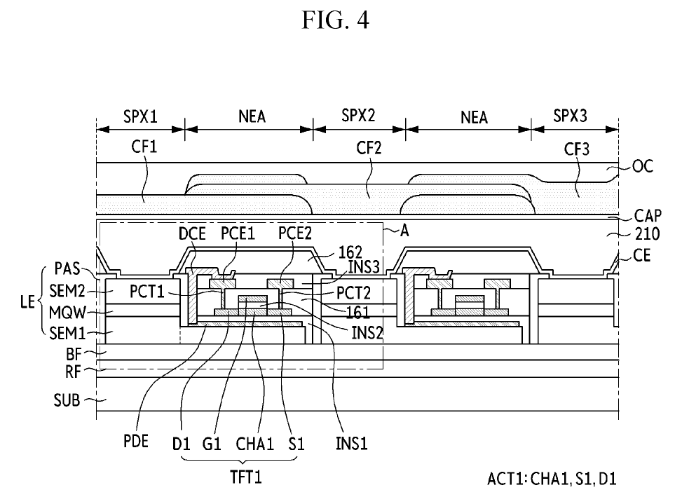

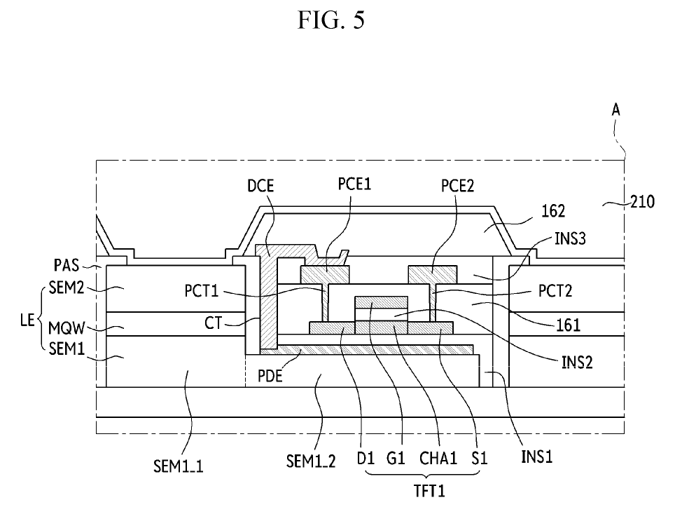

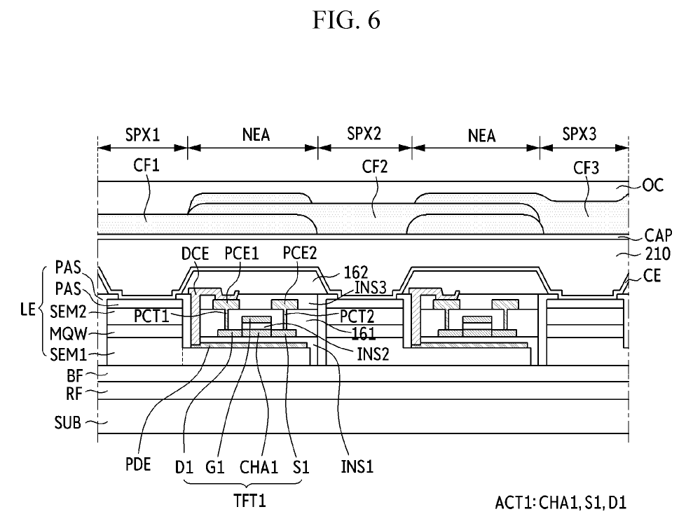

FIG. 4 is a cross-sectional view illustrating an example of one pixel of a display substrate according to one embodiment. FIG. 5 is an enlarged view of area A of FIG. 4 according to one embodiment. FIG. 6 is a cross-sectional view illustrating an example of one pixel of a display substrate according to another embodiment.

Referring to FIGS. 4 and 5, the display device may include a substrate SUB, a reflective layer RF, a buffer layer BF, a light emitting element LE, and a transistor TFT1.

Referring to FIGS. 4 and 5, the substrate SUB may have a deformation temperature of 650 degrees Celsius (°C) or less. For example, it may be made of an insulating material (e.g., an electrically insulating material) such as glass, a polymer resin, and/or the like. When the substrate SUB is made of a polymer resin, it may be a flexible substrate that may be stretched. The polymer resin may be an acrylic resin, an epoxy resin, a phenolic resin, a polyamide resin, and/or a polyimide resin.

The substrate SUB may include a light emitting area SPX1, SPX2, and SPX3 and a non-emission area NEA. The light emitting area SPX1, SPX2, and SPX3 may be referred to as a pixel area or a first area, and the non-emission area NEA may be referred to as a second region.

A reflective layer RF may be on the substrate SUB. The reflective layer RF may be formed of a metal having a high reflectivity, such as silver (Ag) and/or aluminum (Al). The reflective layer RF may reflect light emitted downward from the light emitting layer MQW of the light emitting element LE and transmit it upward. Therefore, because the light loss of the light emitting element LE may be reduced, the light efficiency of the light emitting element LE may be increased.

A buffer layer BF may be on the reflective layer RF. The buffer layer BF may be a layer to facilitate the deposition of a semiconductor thin film of the light emitting element LE. The buffer layer BF may help the plurality of semiconductor layers of the light emitting element LE to have a single crystal plane.

In one embodiment, the buffer layer BF may be composed of at least one selected from aluminum nitride and zinc oxide.

A light emitting element LE and a thin film transistor TFT may be provided side by side on the buffer layer BF. Being provided side by side may mean that the top surfaces of the light emitting element LE and the thin film transistor TFT are on the same plane.

Each of the plurality of light emitting elements LE may be formed of an inorganic material such as gallium nitride (GaN).

Each of the plurality of light emitting elements LE may include a first semiconductor layer SEM1, a light emitting layer MQW, a second semiconductor layer SEM2, and a protective film PAS.

The first semiconductor layer SEM1 may be on the buffer layer BF. The first semiconductor layer SEM1 may be one selected from InAlGaN, GaN, AlGaN, InGaN, AlN, and InN doped with n-type dopants such as Si, Ge, Sn, and/or the like.

The first semiconductor layer SEM1 may be n-GaN doped with n-type Si. The first semiconductor layer SEM1 may include a first portion SEM1_1 having a first thickness T1 and a second portion SEM1_2 having a second thickness T2 lower than the first thickness T1.

The light emitting layer MQW may be on the first portion SEM1_1 of the first semiconductor layer SEM1. The light emitting layer MQW may emit light by the combination of electron-hole pairs according to an electric signal applied through the first semiconductor layer SEM1 and the second semiconductor layer SEM2.

The light emitting layer MQW may include a material having a single or multiple quantum well structure. When the light emitting layer MQW includes a material having a multiple quantum well structure, it may have a structure in which a plurality of well layers and barrier layers are alternately laminated. In embodiments, the well layer may be formed of InGaN, and the barrier layer may be formed of GaN and/or AlGaN but is not limited thereto. In embodiments, the light emitting layer MQW may have a structure in which semiconductor materials having a large band gap energy and semiconductor materials having a small band gap energy are alternately laminated and may include other group III to group V semiconductor materials depending on the wavelength of the light emitted.

When the light emitting layer MQW includes InGaN, the color of the light emitted may suitably vary depending on the content of indium (In). For example, as the content of indium (In) increases, the wavelength band of the light emitted by the light emitting layer may shift to the red wavelength band, and as the content of indium (In) decreases, the wavelength band of the light emitted by the light emitting layer may shift to the blue wavelength band. For example, the content of indium (In) in the light emitting layer MQW of the light emitting element LE emitting the third light (light in the blue wavelength band) may be approximately 10 wt% to 20 wt%.

The second semiconductor layer SEM2 may be on the light emitting layer MQW. The second semiconductor layer SEM2 may be one of InAlGaN, GaN, AlGaN, InGaN, AlN, AlN, and InN doped with p-type dopants such as Mg, Zn, Ca, Se, Ba, and/or the like. For example, the second semiconductor layer SEM2 may be p-GaN doped with p-type Mg.

An undoped semiconductor layer may be further between the first semiconductor layer SEM1 and the buffer layer BF. The undoped semiconductor layer is a semiconductor material layer in which an n-type dopant is lower than a set or predetermined threshold value and may be referred to as an undoped semiconductor layer. For example, the undoped semiconductor layer may be indium aluminum gallium nitride (InAlGaN), gallium nitride (GaN), aluminum gallium nitride (AlGaN), indium gallium nitride (InGaN), aluminum nitride (AlN), and/or indium nitride (InN) having an n-type dopant lower than a set or predetermined threshold value.

The electron blocking layer may be between the second semiconductor layer SEM2 and the light emitting layer MQW. The electron blocking layer may be a layer to suppress or prevent too many electrons from flowing into the light emitting layer MQW (or to reduce a flow thereof). For example, the electron blocking layer may be AlGaN and/or p-AlGaN doped with p-type Mg. The electron blocking layer may be omitted.

The superlattice layer may be between the light emitting layer MQW and the first semiconductor layer SEM1. The superlattice layer may be a layer to relieve stress between the first semiconductor layer SEM1 and the light emitting layer MQW. For example, the superlattice layer may be formed of InGaN and/or GaN. The superlattice layer may be omitted.

Referring to FIG. 6, a conductive layer E1 (e.g., an electrically conductive layer E1) may be further included on the second semiconductor layer SME2. The conductive layer E1 may be on one surface of the first semiconductor layer SEM1. In FIG. 6, the conductive layer E1 is illustrated as covering the entire bottom surface of the first semiconductor layer SEM1 as an example, but the embodiment of the present disclosure is not limited thereto. For example, the conductive layer E1 may be on a portion of the bottom surface of the first semiconductor layer SEM1. The conductive layer E1 may include one of molybdenum (Mo), aluminum (Al), chromium (Cr), gold (Au), titanium (Ti), nickel (Ni), neodymium (Nd), and/or copper (Cu).

The protective film PAS may be around (e.g., surround) the side surface and one surface of the light emitting element LE. The protective film PAS may not be on the outer surface of the second portion SEM1_2. The protective film PAS may have an opening that exposes at least a portion of the top surface of the light emitting element LE. At least a portion of the second semiconductor layer SME2 may be exposed through the opening.

A pad electrode PDE may be on a second portion SEM1_2 of the first semiconductor layer SEM1. The pad electrode PDE may include one of molybdenum (Mo), aluminum (Al), chromium (Cr), gold (Au), titanium (Ti), nickel (Ni), neodymium (Nd), and/or copper (Cu).

A pad insulating layer INS1 (e.g., a pad electrically insulating layer INS1) may be on the pad electrode PDE.

A thin film transistor TFT1 may be on the pad insulating layer INS1. The thin film transistor TFT1 may be one of the fourth transistor ST4 and the sixth transistor ST6 shown in FIG. 3. The thin film transistor TFT1 may include a first active layer ACT1 and a first gate electrode G1.

The first active layer ACT1 of the thin film transistor TFT1 may be on an insulating layer INS1 (e.g., an electrically insulating layer INS1). The first active layer ACT1 of the thin film transistor TFT1 may include polycrystalline silicon, monocrystalline silicon, low-temperature polycrystalline silicon, or amorphous silicon. In embodiments, the first active layer ACT1 of the thin film transistor TFT1 may be formed of an oxide semiconductor including IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

The first active layer ACT1 may include a first channel area CHA1, a first source area S1, and a first drain area D1. The first channel area CHA1 may be a region that overlaps the first gate electrode G1 in a third direction DR3 that is a thickness direction of the substrate SUB. The first source area S1 may be on one side of the first channel area CHA1, and the first drain area D1 may be on the other side of the first channel area CHA1. The first source area S1 and the first drain area D1 may be regions that do not overlap the first gate electrode G1 in the third direction DR3. The first source area S1 and the first drain area D1 may be regions in which ions are doped into a semiconductor material to have conductivity (e.g., electrical conductivity).

A gate insulating layer INS2 (e.g., a gate electrically insulating layer INS2) may be on the first channel area CHA1, the first source area S1, and the first drain area D1 of the thin film transistor TFT1. The gate insulating layer INS2 may be formed of an inorganic film, such as a silicon nitride layer, a silicon oxynitride layer, a silicon oxide layer, a titanium oxide layer, and/or an aluminum oxide layer.

A first gate electrode G1 of the thin film transistor TFT1 may be on the gate insulating layer INS2. The first gate electrode G1 may overlap the first active layer ACT1 in the third direction DR3. The first gate electrode G1 may be formed as a single layer or a plurality of layers made of one of molybdenum (Mo), aluminum (Al), chromium (Cr), gold (Au), titanium (Ti), nickel (Ni), neodymium (Nd), and/or copper (Cu), and/or an alloy thereof.

A first organic layer 161 may be provided to flatten the step of the thin film transistor TFT1. The first organic layer 161 may be formed of an organic film such as an acrylic resin, an epoxy resin, a phenolic resin, a polyamide resin, a polyimide resin, and/or the like.

A drain electrode PCE1 and a source electrode PCE2 may be on the first organic layer 161. The drain electrode PCE1 and the source electrode PCE2 may be connected to the second active layer ACT2 through a first transistor connection hole PCT1 and a second transistor connection hole PCT2 that penetrates the first organic layer 161. For example, the drain electrode PCE1 may be connected to the first drain area D1 through the first transistor connection hole PCT1, and the source electrode PCE2 may be connected to the first source area S1 through the second transistor connection hole PCT2.

The drain electrode PCE1 and the source electrode PCE2 may include a first layer made of titanium (Ti), a second layer made of aluminum (Al), and a third layer made of titanium (Ti).

A transistor insulating layer INS3 (e.g. a transistor electrically insulating layer INS3) may be included on the drain electrode PCE1 and the source electrode PCE2. The transistor insulating layer INS3 may be made of the same material as the first organic layer 161 or the same material as the protective film PAS.

The transistor insulating layer INS3 may include an opening that exposes at least a portion of the drain electrode PCE1.

A pad connection electrode DCE may be on the drain electrode PCE1 exposed through the opening. The pad connection electrode DCE may be connected to the pad electrode PDE through a connection hole CT that penetrates the transistor insulating layer INS3, the first organic layer 161, and the pad insulating layer INS1. Because the drain area D1 of the thin film transistor TFT1 and the first semiconductor layer SEM1 of the light emitting element LE are connected, a voltage controlled by the thin film transistor TFT1 may be applied to the first semiconductor layer SEM1.

The second organic layer 162 covers the thin film transistor TFT1 between the light emitting elements LE and the light emitting elements LE. The second organic layer 162 may be only in the non-emission area NEA and may have an island shape in the flat surface. The second organic layer 162 may secure a distance between the thin film transistor TFT1 and the common electrode CE to prevent or reduce the occurrence of a wiring parasitic capacitor.

The second organic layer 162 does not cover the light emitting element LE.

A common electrode CE may be on the second organic layer 162 and the light emitting element LE. The common electrode CE may be connected to the second semiconductor layer SME2 of the light emitting element LE exposed by the protective film PAS. The common electrode CE may include a transparent metal material (TCO) such as indium tin oxide (ITO) and/or indium zinc oxide (IZO), which may transmit light.

A third organic layer 210 may be on the common electrode CE. The third organic layer 210 may serve as an encapsulation layer.

A capping layer CAP may be on the third organic layer 210. The capping layer CAP may be formed from an inorganic film, such as silicon nitride (SiNₓ), silicon oxide (SiON), silicon oxide (SiOₓ), titanium oxide (TiOₓ), and/or aluminum oxide (AlOₓ).

A plurality of color filters CF1, CF2, and CF3 may be on the capping layer CAP. The plurality of color filters CF1, CF2, and CF3 may include first color filters CF1, second color filters CF2, and third color filters CF3.

The first color filter CF1 on the first sub-pixel SPX1 may transmit first light (light in a red wavelength band) and absorb and/or block third light (light in a blue wavelength band). Therefore, the first sub-pixel SPX1 may emit the first light (light in the red wavelength band).

The second color filter CF2 provided in the second sub-pixel SPX2 may transmit the second light (light in the green wavelength band) and absorb and/or block the third light (light in the blue wavelength band). Therefore, the second sub-pixel SPX2 may emit the second light (light in the green wavelength band).

The third color filter CF3 provided in the third sub-pixel SPX3 may transmit the third light (light in the blue wavelength band). Therefore, the third sub-pixel SPX3 may emit the third light (light in the blue wavelength band).

The first color filter CF1, the second color filter CF2, and the third color filter CF3 that overlap in the third direction DR3 may overlap the non-emission area NEA in the third direction DR3.

A fourth organic layer OC for planarization may be on the plurality of color filters CF1, CF2, and CF3.

Hereinafter, a manufacturing process of a display device 10 according to one embodiment will be described with reference to the drawings.

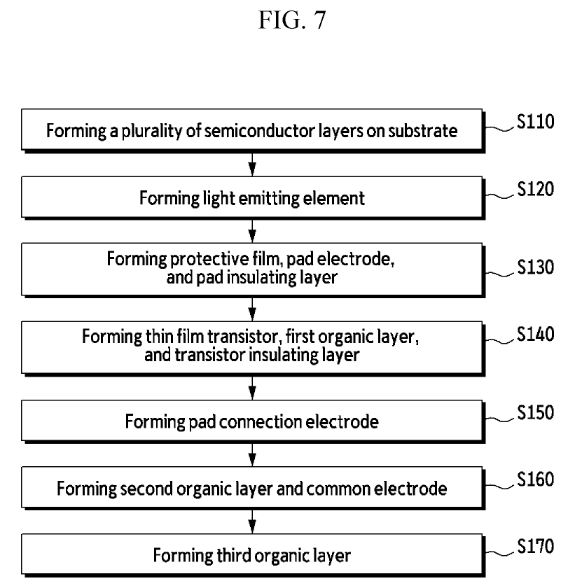

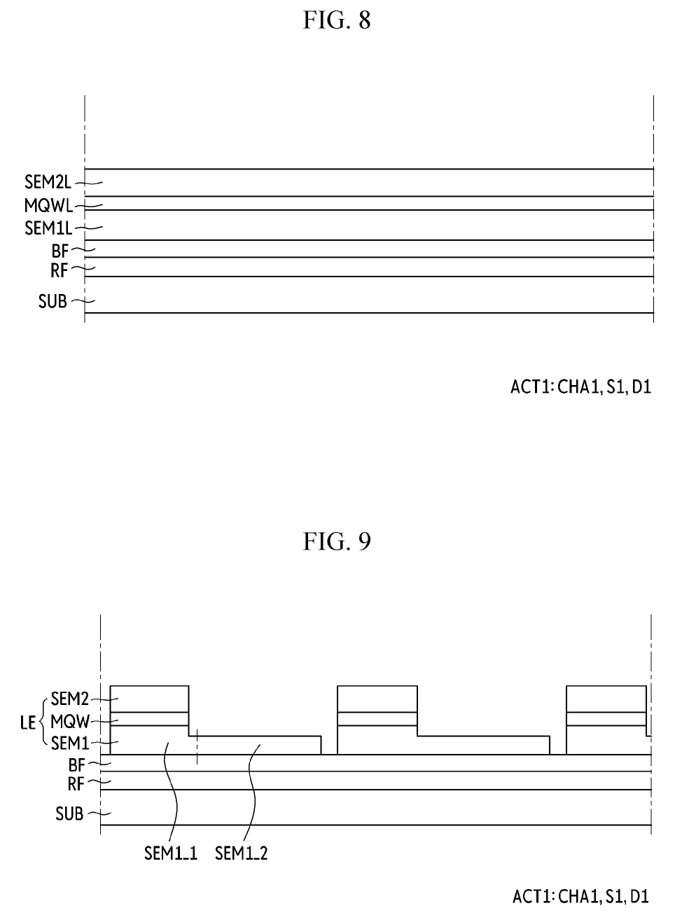

FIG. 7 is a flowchart illustrating a method of manufacturing a display device according to one embodiment. FIGS. 8 to 17 are example drawings to illustrate a method of manufacturing a display device according to one embodiment.

Hereinafter, a method for manufacturing a display device according to one embodiment will be described in more detail by connecting FIG. 7 with FIGS. 8 to 17. FIGS. 8 to 17 mainly illustrate the manufacturing process of a light emitting element LE and a transistor TFT1, which may generally correspond to a portion of the drawing of FIG. 4, respectively. In the following description of the manufacturing method, the materials of each layer are described above, so redundant description thereof may not be repeated.

First, as shown in FIG. 8, a plurality of semiconductor layers SEM1L, MQWL, and SEM2L on a substrate SUB may be formed. (S110 in FIG. 7)

For example, a substrate SUB is prepared. The substrate SUB may be at least one selected from a glass substrate, a stainless-steel substrate, and a polymer substrate having a transformation temperature of 650 degrees Celsius (°C) or less.

A reflective layer RF is formed on the substrate SUB. The reflective layer RF may be formed by depositing a metal material that is easy to reflect on the entire surface of the substrate SUB. The metal material that is easy to reflect may include, for example, at least one selected from Ag and Al. The light emitted from the light emitting element LE may be reflected by the reflective layer RF to increase the amount of light emitted from the top of the light emitting element LE and the light extraction efficiency.

A buffer layer BF may be formed on the reflective layer RF. The buffer layer BF may be a layer for easily growing a semiconductor layer.

The buffer layer BF may help the plurality of semiconductor layers SEM1L, MQWL, and SEM2L to have a single crystal plane. The buffer layer BF may include a hexagonal structure. The buffer layer BF may be composed of at least one selected from aluminum nitride and zinc oxide.

A plurality of semiconductor layers SEM1L, MQWL, and SEM2L may be grown on the buffer layer BF.

The first semiconductor layer SEM1L may be an n-type semiconductor layer, and the second semiconductor layer SEM2L may be a p-type semiconductor layer.

Representative technologies for depositing semiconductor layers include MOCVD (Metal Organic CVD) and MBE (Molecular Beam Epitaxy). The substrate 100 temperature should be maintained at about 1,000 degrees Celsius (°C) to 1,100 degrees Celsius (°C) to deposit a semiconductor layer by these methods. Therefore, when using MOCVD (Metal Organic CVD) method and MBE (Molecular Beam Epitaxy) method, the substrate 100 on which the semiconductor thin film is formed is limited to single crystal sapphire (Al₂O₃), silicon (Si), silicon carbide (SiC), and/or the like, which have relatively high transformation temperatures. It is difficult to produce large-area wafers of 12 inches or more using single crystal sapphire (Al₂O₃), silicon (Si), silicon carbide (SiC), and/or the like, and the production cost is high, making it difficult to implement large-area displays such as a large TV.

When growing a semiconductor thin film on a sapphire substrate, because a transfer process to transfer a light emitting element LE to a substrate SUB made of glass is utilized in the process of manufacturing a micro LED, there is a problem that the production cost of the light emitting element LE significantly increases due to the transfer process.

To solve this problem, the semiconductor thin film of the light emitting element LE of the present disclosure may be grown at a low temperature by supplying additional energy to the physical deposition method and the chemical deposition method. For example, the physical deposition method used in the thin film growth process may be at least one selected from a sputtering method, an e-beam deposition method, and a thermal deposition method. The additional energy supplied to the substrate SUB in the thin film growth process step may be at least one selected from ion beam, electron beam, plasma, ultraviolet ray, the laser, and the LED light. In this way, by providing a sputtering ion beam in the thin film growth process, a portion of the energy utilized or required for semiconductor layer deposition is provided as the kinetic energy of the ion beam, thereby lowering the growth temperature of the semiconductor thin film in the existing process.

When ion beam sputtering is used, the nitride semiconductor layer may be deposited on a substrate SUB having a transformation temperature of 650 degrees Celsius (℃) or less. When the nitride semiconductor layer is directly deposited on the substrate SUB, unlike when the nitride semiconductor layer is deposited on a sapphire substrate, the light emitting element LE may be directly manufactured on the backplane.

In one embodiment, at least one selected from helium (He), neon (Ne), argon (Ar), krypton (Kr), xenon (Xe), radon (Rn), hydrogen (H₂), oxygen (O₂), nitrogen (N₂), chlorine (Cl₂), and ammonia (NH₃) may be used for ion beam sputtering.

In one embodiment, the sputtering target used for the ion beam sputtering may include gallium (Ga) and/or gallium nitride (GaN).

When the thin film deposition process of the semiconductor layer is performed at a relatively low temperature, the range of substrates available for the manufacturing process may be expanded.

In this way, when a semiconductor layer is deposited using ion beam sputtering, the light emitting element LE manufacturing process and the light emitting element LE transfer process may be omitted in the display device manufacturing process. Therefore, when the display device manufacturing process according to one embodiment is applied to a large-area display device, it is more beneficial or advantageous in terms of manufacturing cost.

Second, a double mask is formed to etch the semiconductor layer to form the light emitting element LE. (S120 in FIG. 7)

The plurality of semiconductor layers SEM1L, MQWL, and SEM2L may include a first region having a first thickness and a second region having a second thickness. The first region having the first thickness may include a first semiconductor layer SME1, a light emitting layer MQW, and a second semiconductor layer SEM2, and the second region having the second thickness may include the first semiconductor layer SEM1. The first semiconductor layer SEM1 may include a first portion SEM1_1 having a first thickness T1 in the first region and a second portion SEM1_2 having a second thickness T2 in the second region.

Etching may use dry etching. When using a dry etching method, the etching gas may be chlorine (Cl₂) and/or oxygen (O₂) gas but is not limited thereto. By dry etching, the width of the plurality of semiconductor material layers may become wider as they go downward. However, the etching is not limited to dry etching.

Third, a protective film PAS, a pad electrode PDE, and a pad insulating layer INS1 (a pad electrically insulating layer INS1) are formed. (S130 in FIG. 7)

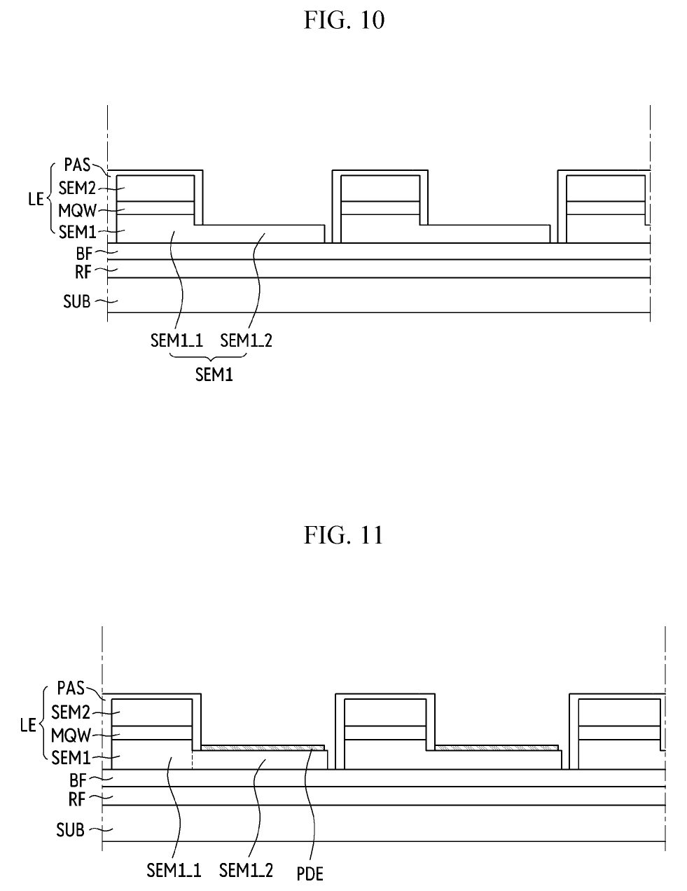

For example, a protective material layer may be deposited on the entire surface of the substrate SUB. The protective material layer may be formed to cover one surface and side surfaces of the light emitting elements LE. Then, a mask may be formed on the semiconductor layer on the first region, and the protective material layer formed on the second region may be removed. In embodiments, the protective material layer exposed between the light emitting elements LE may also be removed. As a result, as shown in FIG. 10, a protective film PAS around (e.g., surrounding) the semiconductor layer in the first region may be formed. The mask may be removed by an ashing process. The thickness of the protective film PAS may minimize or reduce the step difference between the light emitting elements LE in the first region and the thin film transistor TFT1 in the second region.

Referring to FIG. 11, a pad electrode PDE is formed on the second portion SEM1_2 of the first semiconductor layer SEM1.

For example, after the electrode material layer is completely deposited on the substrate, the pad electrode PDE may be formed by leaving the electrode material layer only on the second portion SEM1_2 using a mask.

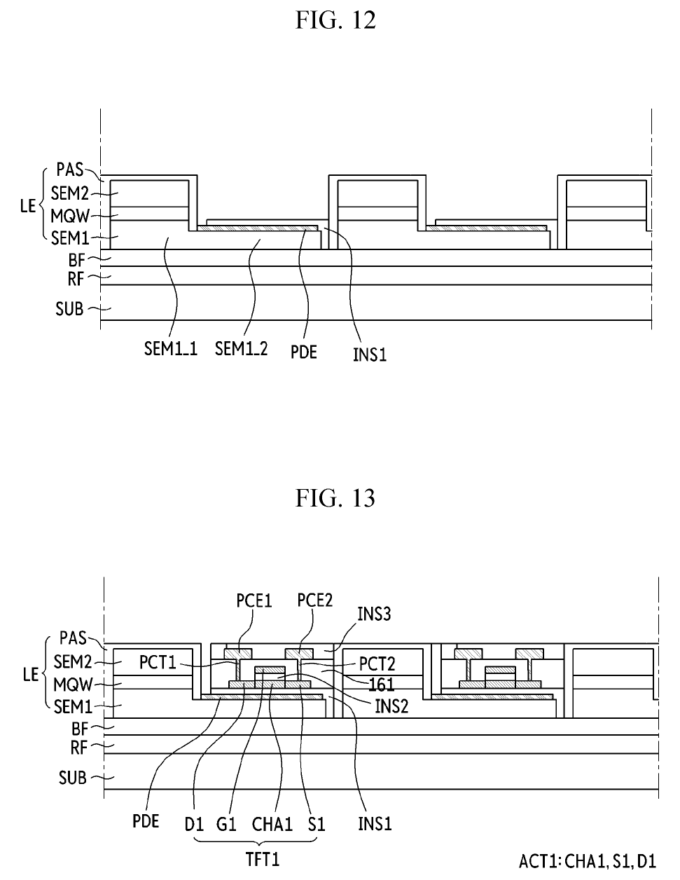

Referring to FIG. 12, a pad insulating layer INS1 (e.g., a pad electrically insulating layer INS1) may be formed to cover the entire pad electrode PDE.

Fourth, a thin film transistor TFT1, a first organic layer 161, and a transistor insulating layer INS3 (e.g., a transistor electrically insulating layer INS3) are formed. (S140 in FIG. 7)

For example, an active layer ACT1 is formed on the pad insulating layer INS1.

The active layer ACT1 may be formed by a mask process. For example, after the oxide semiconductor or silicon is fully deposited on the substrate SUB, the active layer ACT1 as shown in FIG. 13 may be formed by patterning through a photolithography process.

Then, a gate insulating layer INS2 (e.g., a gate electrically insulating layer INS2) is formed on the active layer ACT1, and a first gate electrode G1 overlapping the active layer ACT1 is formed on the gate insulating layer INS2. The first gate electrode G1 may be formed by a mask process. For example, a material layer for a gate electrode is fully deposited on the gate insulating layer INS2. Then, a photoresist layer is applied on the material layer for the gate electrode, and a photoresist pattern is formed through exposure and development, and then the material layer for the gate electrode is etched using this as an etching mask. Thereafter, the photoresist pattern may be removed through a stripping and/or ashing process to form the first gate electrode G1.

Next, a first organic layer 161 covering both the first gate electrode G1 and the active layer ACT1 is formed, and a drain electrode PCE1 and a source electrode PCE2 are formed on the first organic layer 161. The drain electrode PCE1 and the source electrode PCE2 may be formed by the mask process described above. Before forming the drain electrode PCE1 and the source electrode PCE2, contact holes are formed that penetrate the first organic layer 161 and expose the active layer ACT1. Thereafter, a source/drain electrode material layer is entirely deposited on the first organic layer 161 and patterned by a photolithography process to form the drain electrode PCE1 and the source electrode PCE2. The drain electrode PCE1 and the source electrode PCE2 may be respectively connected to the active layer ACT1 through the contact holes. Therefore, a thin film transistor TFT1 including the active layer ACT1, the first gate electrode G1, the drain electrode PCE1, and the source electrode PCE2 is manufactured.

Then, a transistor insulating layer INS3 (e.g., a transistor electrically insulating layer INS3) is formed on the drain electrode PCE1 and the source electrode PCE2. The transistor insulating layer INS3 may be formed by coating an organic material through a solution process, such as spin coating. The transistor insulating layer INS3 flattens the upper portions of the drain electrode PCE1 and the source electrode PCE2, so it may also be called a planarization layer.

Fifth, a pad connection electrode DCE is formed. (S150 in FIG. 7)

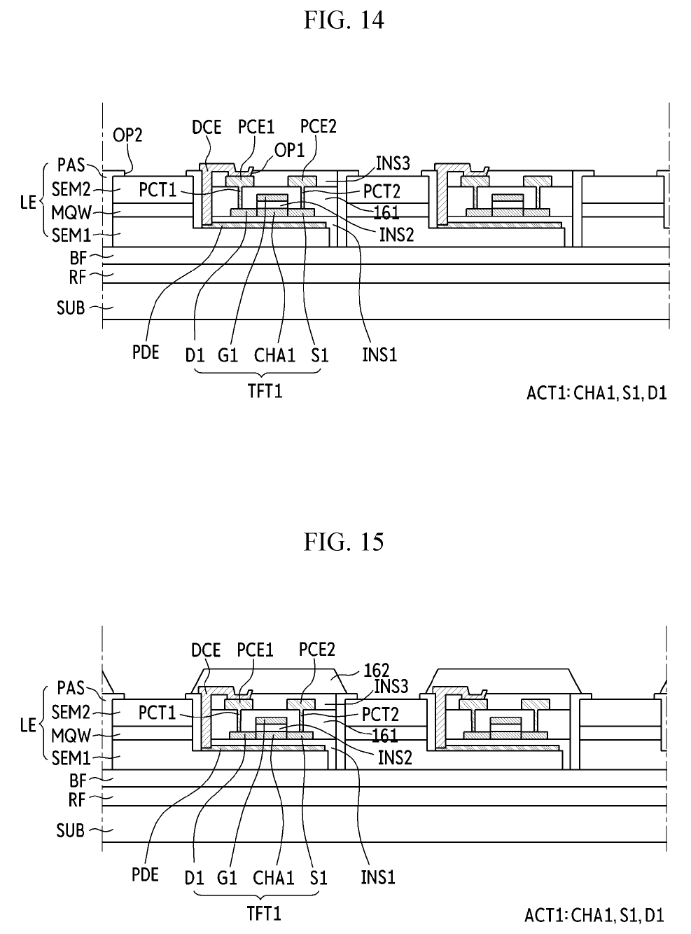

For example, referring to FIG. 14, a first opening OP1 exposing the drain electrode PCE1 of the thin film transistor TFT1 and a second opening OP2 exposing the upper portion of the light emitting element LE are formed through a photolithography process. In embodiments, a connection hole CT penetrating the transistor insulating layer INS3, the first organic layer 161, and the pad insulating layer INS1 is formed through a photolithography process.

Next, a pad connection electrode DCE is formed. The pad electrode PDE may be formed by a physical vapor deposition PVD method and/or a chemical vapor deposition method CVD.

Sixth, a second organic layer 162 and a common electrode CE are formed. (S160 in FIG. 7)

Referring to FIG. 15, an organic material layer is applied on the transistor insulating layer INS3 on which the pad connection electrode DCE is formed, and a second organic layer 162 is formed only in the second region through a photolithography process using a halftone mask.

The drain D1 of the thin film transistor TFT1 and the first semiconductor layer SEM1 are electrically connected through the pad connection electrode DCE.

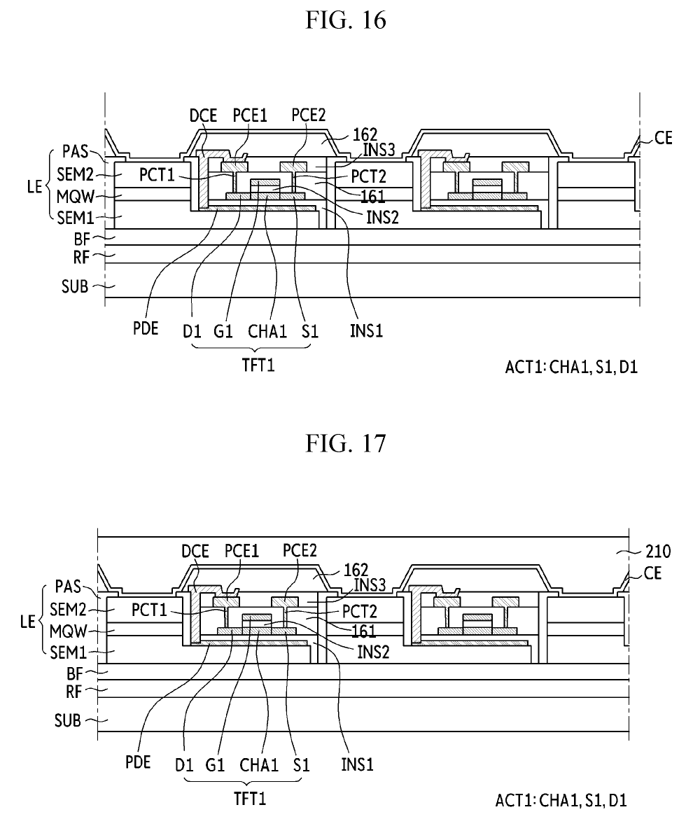

Next, referring to FIG. 16, a common electrode CE is formed on the second organic layer 162 and the light emitting element LE.

The common electrode CE may be formed over the entire surface of the substrate SUB.

Seventh, a third organic layer 210 is formed. (S170 in FIG. 7)

Referring to FIG. 17, the third organic layer 210 may be formed over the entire surface of the substrate SUB.

Then, in embodiments, a color filter layer may be formed over the third organic layer 210 illustrated in FIG. 4.

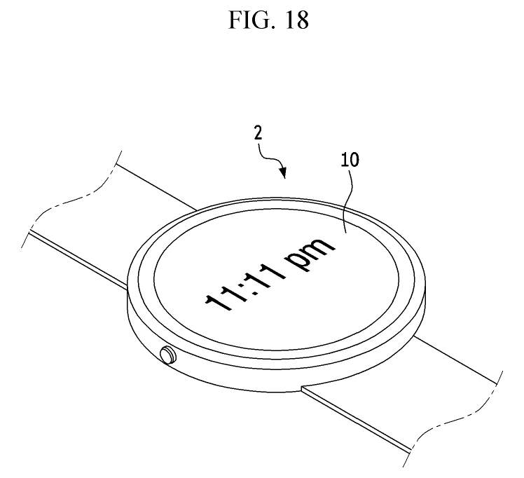

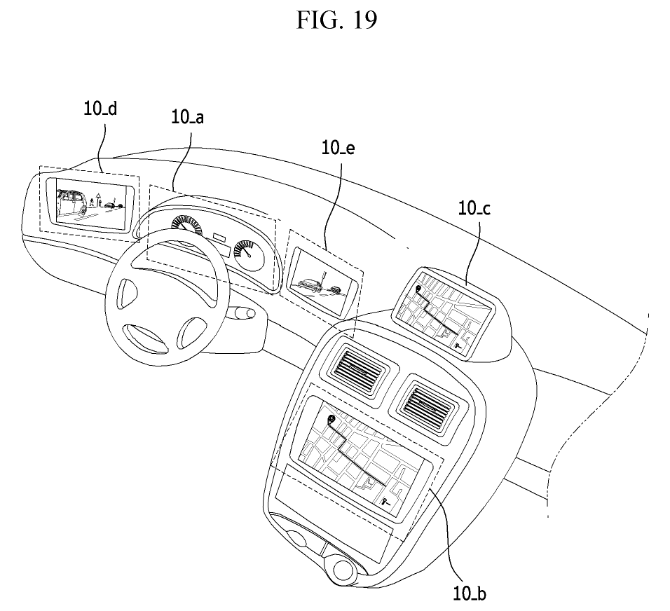

FIG. 18 illustrates a smart device including a display device according to one or more embodiments.

Referring to FIG. 18, a display device 10 according to one or more embodiments may be applied to a smart watch 2 as one of smart devices.

FIG. 19 illustrates a vehicle in which display devices according to one or more embodiments are used.

Referring to FIG. 19, the display devices 10_a, 10_b, or 10_c according to one or more embodiments may be respectively applied to the dashboard of the vehicle, applied to the center fascia of the vehicle, and/or applied to a Center Information Display (CID) on the dashboard of the vehicle. Further, each of the display devices 10_d and 10_e according to one or more embodiments may be applied to each mirror display that replaces each of side-view mirrors of the vehicle.

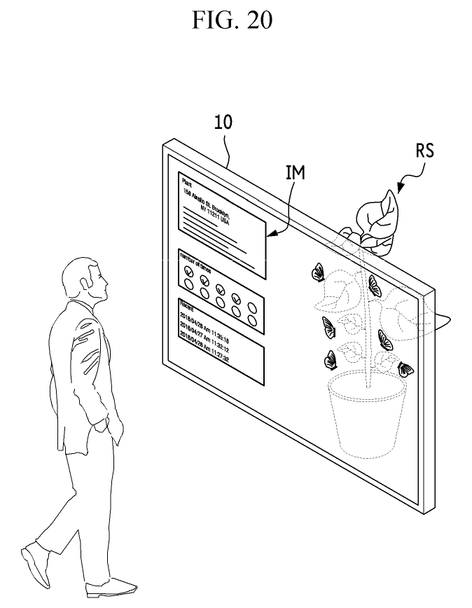

FIG. 20 is an example diagram illustrating a transparent display device including a display device according to one or more embodiments.

Referring to FIG. 20, a display device according to one or more embodiments may be applied to a transparent display device. The transparent display device may transmit light therethrough while displaying an image IM thereon. Therefore, a user in front of the transparent display device may not only view the image IM displayed on the display device 10, but also may view an object RS or a background at a rear of the transparent display device. In embodiments where the display device 10 is applied to the transparent display device, the substrate SUB of the display device 10 shown in FIG. 7 may include a light-transmitting portion that may transmit light therethrough or may be made of a material that may transmit light therethrough.

In concluding the detailed description, those skilled in the art will appreciate that many suitable variations and modifications can be made to the embodiments without substantially departing from the principles and scope of the present disclosure. Therefore, the embodiments of the present disclosure are used in a generic and descriptive sense only and not for purposes of limitation.

However, aspects of embodiments of the present disclosure are not restricted to the ones set forth herein. The above and other aspects of embodiments of the present disclosure will become more apparent to one of ordinary skill in the art to which the present disclosure pertains by referencing the claims, with functional equivalents thereof to be included therein.

What is claimed is:

1. A display device comprising:
a substrate comprising a light emitting area and a non-light-emitting area;
a light emitting element comprising a first semiconductor layer, a light emitting layer, and a second semiconductor layer, wherein the first semiconductor layer comprises a first portion provided in the light emitting area and a second portion provided in the non-light-emitting area;
a pad electrode on the second portion of the first semiconductor layer;
a thin film transistor on the pad electrode;
a pad insulating layer between the pad electrode and the thin film transistor;
a pad connection electrode that connects the thin film transistor and the pad electrode; and
a common electrode on the light emitting element.

2. The display device of claim 1, further comprising a first organic layer that covers a side surface of the transistor;
a source electrode and a drain electrode that penetrates the organic layer and respectively connected to a source and a drain of the transistor; and
a transistor insulating layer that covers the source electrode and the drain electrode, and comprises an opening that exposes at least a portion of the drain electrode, and
wherein the pad connection electrode is on the drain electrode exposed by the transistor insulating layer and contacts the pad electrode that penetrates the transistor insulating layer, the organic layer, and the pad insulating layer.

3. The display device of claim 1, wherein the pad connection electrode is between the light emitting element and the transistor.

4. The display device of claim 1, wherein the light emitting layer is on the first portion, and the second semiconductor layer is on the light emitting layer.

5. The display device of claim 4, wherein the first semiconductor layer is a semiconductor layer doped with an n-type dopant, and the second semiconductor layer is a semiconductor layer doped with a p-type dopant.

6. The display device of claim 5, wherein the light emitting element further comprises a protective layer around a portion of a side surface and a top surface of a semiconductor layer provided in the light emitting area.

7. The display device of claim 5, wherein the light emitting element further comprises a conductive layer on the second semiconductor layer.

8. The display device of claim 1, wherein the light emitting element further comprises an undoped semiconductor layer under the first semiconductor layer.

9. The display device of claim 1, further comprising a reflective layer formed on the substrate; and
a buffer layer formed under the light emitting element above the reflective layer.

10. The display device of claim 1, further comprising a second organic layer above the thin film transistor in the non-emission area and below the common electrode.

11. A method for manufacturing a display device comprising:
forming a first semiconductor layer, a light emitting layer, and a second semiconductor layer on a substrate;
etching the second semiconductor layer, the light emitting layer, and the first semiconductor layer, wherein the first semiconductor layer is formed to have different thicknesses in a first portion and a second portion, thereby forming a light emitting element;
forming a pad electrode on a second portion of the first semiconductor layer;
forming a thin film transistor on the pad electrode; and
forming a pad connection electrode connecting the thin film transistor and the pad electrode.

12. The method of claim 11, wherein the forming a thin film transistor on the pad electrode comprises,
forming a pad insulating layer covering the pad electrode,
forming an active layer including a source area, a channel area, and a drain area on the pad insulating layer,
forming a gate insulating layer on the active layer, and a gate electrode on the gate insulating layer, and then forming a first organic layer covering both the gate electrode and the active layer, and
forming a source electrode connected to the source area and a drain electrode connected to the drain area by penetrating the first organic layer.

13. The method of claim 12, wherein the forming a pad connection electrode connecting the thin film transistor and the pad electrode comprises,
forming a transistor insulating layer covering the source electrode and the drain electrode, and
forming a connection hole penetrating the transistor insulating layer, the first organic layer, and the pad insulating layer to expose the pad electrode and the forming a pad connection electrode connecting the drain electrode and the pad electrode through the connection hole.

14. The method of claim 11, further comprising, prior to forming a first semiconductor layer, a light emitting layer, and a second semiconductor layer on the substrate,
depositing a reflective layer on the substrate; and
forming a buffer layer on the reflective layer.

15. The method of claim 11, wherein a second organic layer covering the pad connection electrode and the transistor is formed, and
wherein a common electrode covering the second organic layer and the light emitting element is formed.

16. The method of claim 11, wherein the substrate is at least one selected from a glass substrate, a stainless-steel substrate, and a polymer substrate.

17. The method of claim 11, wherein the forming the light emitting element further comprises,
forming a protective layer around a side surface and one surface of the first semiconductor layer, the light emitting layer, and the second semiconductor layer of the first portion.

18. The method of claim 11, wherein the pad connection electrode is formed between the light emitting element and the transistor.

19. The method of claim 11, wherein in the forming the first semiconductor layer, the light emitting layer, and the second semiconductor layer on the substrate,
an undoped semiconductor layer is formed between the substrate and the first semiconductor layer, and at least one of a conductive layer is formed on the second semiconductor layer.

20. An electronic device comprising a display panel,
the display panel comprising: a substrate comprising a light emitting area and a non-light-emitting area;
a light emitting element comprising a first semiconductor layer, a light emitting layer, and a second semiconductor layer, wherein the first semiconductor layer comprises a first portion provided in the light emitting area and a second portion provided in the non-light-emitting area;
a pad electrode on the second portion of the first semiconductor layer;
a thin film transistor on the pad electrode;
a pad insulating layer between the pad electrode and the thin film transistor;
a pad connection electrode that connects the thin film transistor and the pad electrode; and
a common electrode on the light emitting element.
